(19) United States
(12) Patent Application Publication
(10) Pub. No.: US 2004/0021213 A1
(43) Pub. Date: Feb. 5, 2004

(54) Thermally-enhanced integrated circuit package

(76) Inventors: Shin Shern Low, Plano, TX (US); Mike Pierce, Plano, TX (US)

Correspondence Address: TEXAS INSTRUMENTS INCORPORATED, P O BOX 655474, M/S 3999, DALLAS, TX, 75265

(21) Appl. No.: 10/212,501

(22) Filed: Aug. 5, 2002

(51) Int. Cl. H01L 23/48

(52) U.S. Cl. 257/690

(57) ABSTRACT

A packaged integrated circuit including a substrate 520 including a metal grid 570, 580 over a top surface of the substrate and an integrated circuit chip 500 mounted on the substrate over the grid. The metal grid can be electrically isolated from the integrated circuit or it can be electrically connected to the integrated circuit, through electrical ground for example.

### BACKGROUND OF THE INVENTION

This invention is in the field of integrated circuit packages and packaging methods.

The demand for a reduction in size and an increase in complexity and performance of electronic components has driven the industry to produce smaller and more complex integrated circuits (ICs). These same trends have forced the development of IC packages having small footprints, high lead counts, and better electrical and thermal performance. At the same time, these IC packages are required to meet accepted industry standards. Power dissipation is a particular challenge since high performance ICs produce more thermal energy, and the smaller packages of today allow the designer few options through which to dissipate this energy. While heatsinks or heatslugs attached to the IC package are a common solution to excess heat, they result in a package that is relatively large, expensive, and complicated to produce. The use of a heatsink is particularly difficult in chip-scale plastic ball grid array packages. Package designs that provide an alternative to the use of a heatsink are needed.

FIG. 1 is a cut-away view of a molded chip scale package having an integrated circuit chip 100 positioned with bond pads 105 on its active surface 110 bonded with wires 115 to a flexible tape substrate 120. The flexible tape substrate includes bonding lands 125 and conductive traces 130 on the first or chip side surface 135. The chip 100 is affixed to the flexible tape substrate 120 by a die attach adhesive 140. Vias 145 through the substrate allow connection of the conductive traces 130 on the first surface 135 to solder balls 150 on the opposite or second surface 137 of the substrate 120. A via cap metal 155 provides the base to which solder balls 150 are attached with solder paste. Solder balls 150 are the means by which the chip package is attached to a printed circuit board. An epoxy molding compound 160 encapsulates the top and sides of the chip as well as the bonding wires. Encapsulant 160 provides the form factor of a plastic package, as well as environmental and mechanical protection of the IC.

FIG. 2 is a cross-sectional view of the package shown in FIG. 1. Substrate 220 has been punched through to form via 145. Via cap metal 155 has been formed on the substrate to provide a base to which solder ball 150 is attached. Chip 100 is attached to substrate 120 with die attach adhesive 140. Encapsulant 160 covers chip 100 as well as the remainder of the assembly.

FIG. 3 is a plan view of the substrate 120 shown in FIG. 1. Lands 125 are shown connected to via cap metal 155 by traces 130. Vias 145 are shown in this view, but one skilled in the art will appreciate that the vias are beneath the via cap metal and are only shown in this view to aid understanding of the relation of the various components of the substrate.

It can be seen from FIGS. 1, 2, and 3 that the electrical routing of the circuitry is as follows: chip circuits are routed to bond pads 105 near the chip perimeter by means of thin film wafer processing technology, wires 115 connect the bond pads 105 to lands 125 on the substrate perimeter, conductors 130 connected from the bond wire lands 125 are routed on the first surface 135 of the substrate to vias 145 capped by via cap metal 155, and the vias in turn provide connection to an array of solder balls 150 mounted on the second or bottom surface 137 of the substrate. The package is clearly small, only slightly larger than the IC it contains, and possesses little means for dissipating the heat generated by IC 100 other than through solder balls 150 and traces 130. However, the substrate is typically thermally as well as electrically insulative, so the thermal path from the chip through the substrate out to the solder balls is very inefficient. The addition of a heatsink would help, but would complicate and dramatically increase the expense of this otherwise very small and cost-attractive package.

In an effort to overcome the thermal disadvantages of such a small and inexpensive package, one prior art approach has been to place electrically-unconnected solder balls beneath the IC. These thermal solder balls serve no electrical role, but are additional means for removing heat from the package and transferring it onto the printed circuit board to which the package is later soldered. FIG. 4 is a cutaway view of a package that implements this approach. Via cap metal 455 to which thermal solder balls 450 are attached are unconnected by conductors to any other land. Their purpose is simply to provide additional thermal paths for the dissipation of heat generated by IC 100 out of the package and onto the printed circuit board to which the package is ultimately attached. The printed circuit board must also be designed to connect to these thermal balls and to provide a path through which heat can be dissipated. While effective, this approach is expensive to implement, particularly since a given substrate is typically designed to accommodate a variety of ICs, some of which require this additional heat dissipation capability and some do not. A manufacturer would seek to avoid using thermal solder balls on packages that do not require the additional heat dissipation since mounting the additional balls would add disproportionate cost to the package and provide greater chance for lower device yield. The costs involved in designing the printed circuit board to make use of the thermal balls must also be comprehended. Therefore, the manufacturer would ideally possess the capability to choose between two different substrate designs, one that incorporates the thermal vias and balls and one that does not. This design flexibility means that a manufacturer would need at least two punch tools (or similar means for forming the vias), one that punches a via pattern in the substrate that includes the vias for the thermal solder balls, and one that does not. The cost of such a punch tool is prohibitive and cannot be justified in economic terms for many IC designs. Therefore, there is a need in the industry for a new approach that avoids the high cost and complication of not only the use of heatsinks, but of thermal solder balls as well.

### BRIEF SUMMARY OF THE INVENTION

In one embodiment of the invention, a packaged integrated circuit is disclosed. The packaged IC includes a substrate including a metal grid over a top surface of the substrate and an integrated circuit chip mounted on the substrate over the grid. The metal grid can be electrically isolated from the integrated circuit or it can be electrically connected to the integrated circuit, through electrical ground for example.

In another embodiment of the invention, another packaged integrated circuit is disclosed. The packaged IC includes a substrate having a central portion and a peripheral portion, including vias in the peripheral portion and no vias in the central portion of the substrate. The vias in the peripheral portion are covered on one side of the substrate with metal caps which are formed in a layer of metal. The substrate also includes a metal grid in its central portion, and the metal grid is formed in the layer of metal. In this embodiment, the metal grid is made up of interconnected via cap patterns. The integrated circuit chip is mounted on the substrate over the grid.

In still another embodiment of the invention, a method is disclosed for fabricating a packaged integrated circuit. The method includes the steps of providing a substrate; forming a metal grid on a central portion of the substrate; and mounting an integrated circuit chip over the metal grid. The method can also include the step of electrically isolating the metal grid from the integrated circuit. Or, in the alternative, the method can include the step of electrically connecting the metal grid to the integrated circuit, through electrical ground for example.

An advantage of the invention is that it provides a very cost efficient way of dissipating heat from a packaged IC.

### BRIEF DESCRIPTION OF THE SEVERAL VIEWS OF THE DRAWINGS

FIG. 1 is a cutaway view of a prior art integrated circuit chip in a chip-scale ball grid array package;

FIG. 2 is a cross-sectional view of a portion of the prior art packaged chip shown in FIG. 1 showing via and solder ball detail;

FIG. 3 is a plan view of a prior art substrate of the type used in chip-scale ball grid array packages;

FIG. 4 is a cutaway view of a prior art ball grid array package which incorporates thermal vias and solder balls beneath the chip;

FIG. 5 is a cutaway view of an embodiment chip-scale ball grid array package in which a metal grid serves to dissipate heat generated by the integrated circuit chip;

FIG. 6 is a cross-sectional view of a portion of the package shown in FIG. 5 showing detail of the via, via cap metal, solder ball, as well as the via cap pattern and cross-links which comprise the metal grid;

FIG. 7 is a plan view of an embodiment substrate in which the metal grid is electrically isolated from the chip which is mounted over it;

FIG. 8 is a detailed view of a portion of the substrate shown in FIG. 7;

FIGS. 9a and 9b are embodiment substrates in which the metal grid is coupled to the exterior of the package through via caps attached to solder balls;

FIG. 10 is a detailed view of a portion of the substrate shown in FIG. 9a; and

FIG. 11 is a plan view of an embodiment substrate in which the metal grid is interleaved between vias and solder balls arranged uniformly across the substrate in an area array pattern.

### DETAILED DESCRIPTION OF THE INVENTION

In various embodiments of the invention described herein, a metal pattern is made on the portion of a substrate upon which a chip is mounted. The metal pattern is superior to the substrate in its ability to conduct and radiate thermal energy. The pattern can take a variety of forms, including that of a solid sheet of metal beneath the chip. The embodiments shown herein include metal grid patterns advantageously designed to conform to the existing design rules used in forming the substrate.

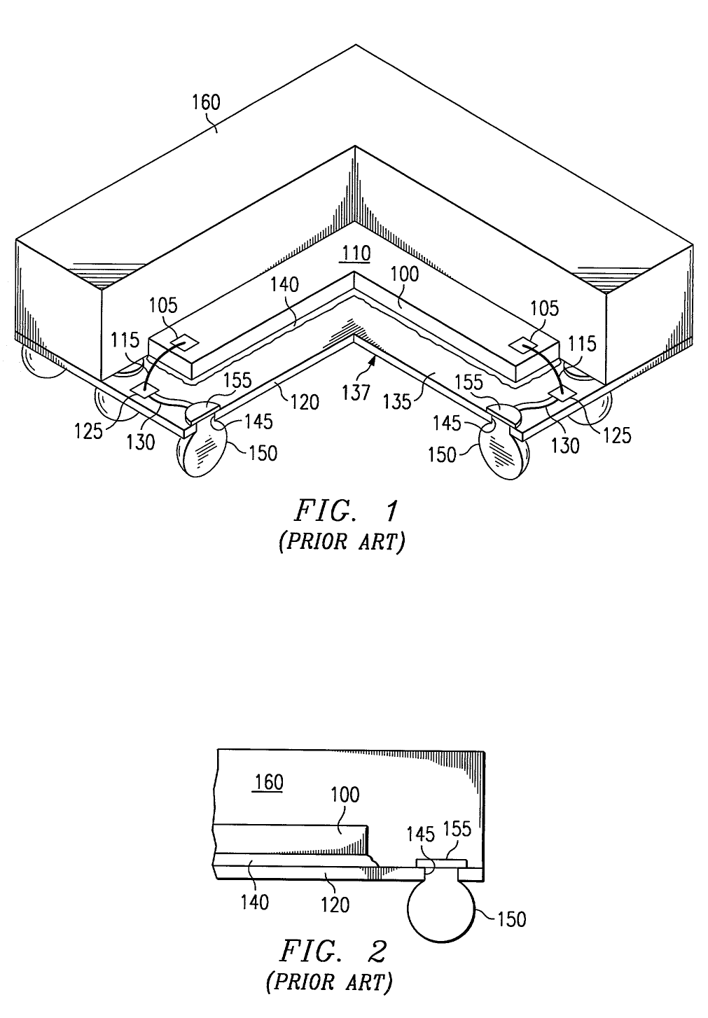

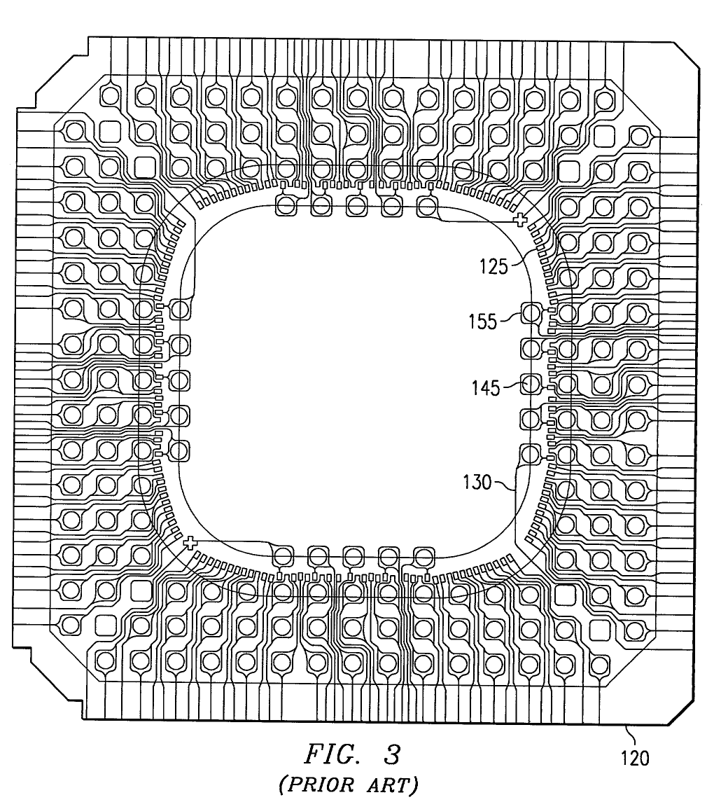

In a first preferred embodiment of the invention, a grid of via cap metal under the chip dissipates heat generated by the chip. No vias or solder balls are used beneath these via caps, a fact which eliminates the need for a special punch tool or other means to create vias and also eliminates the expense associated with placing and attaching additional solder balls. The embodiment approach results in a thermal solution that costs approximately 3% of the prior art solution by eliminating the vias and solder balls under the chip dedicated solely to thermal dissipation. The via caps are preferably coupled to one another to create a grid or mesh of via cap metal beneath the chip. Research by the inventors has shown that a 5% to 10% improvement in heat dissipation may be achieved using this approach as compared to the package shown in FIG. 1. Furthermore, the grid of via caps beneath the chip provides the additional advantage of constraining the bending of the substrate that occurs during thermal cycling of the package. Such bending is known to result from differences in the coefficient of thermal expansion (CTE) of the various package components. Additional metal (e.g. copper) on the substrate assists in balancing the CTE disparity. It also physically constrains substrate bending by virtue of its being adhesively attached to the substrate.

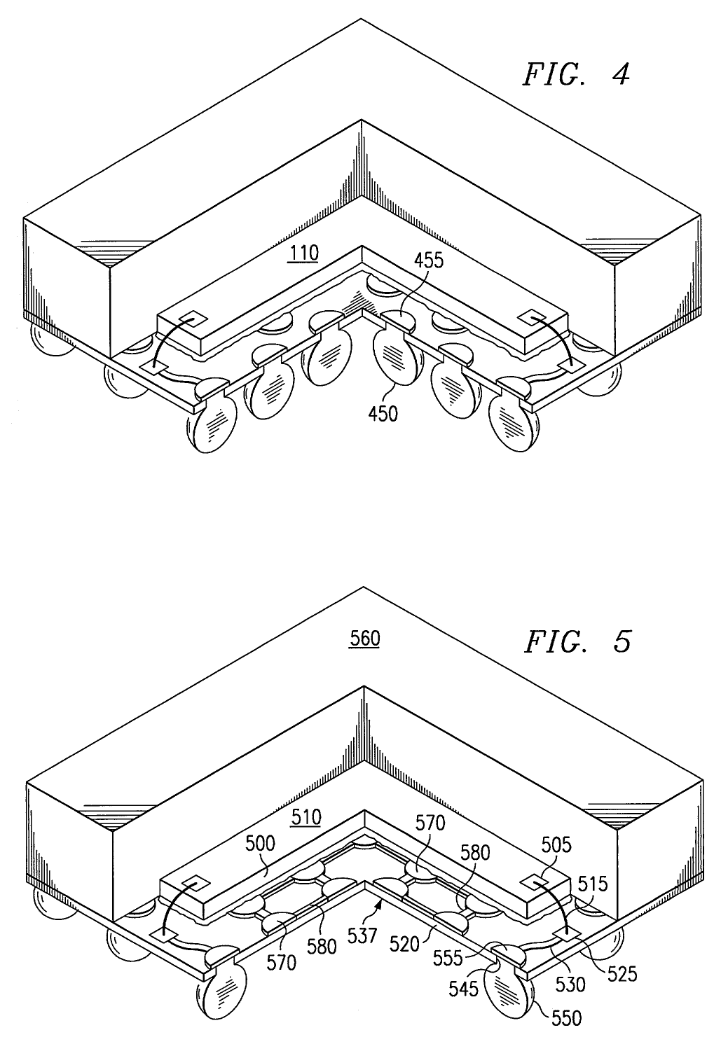

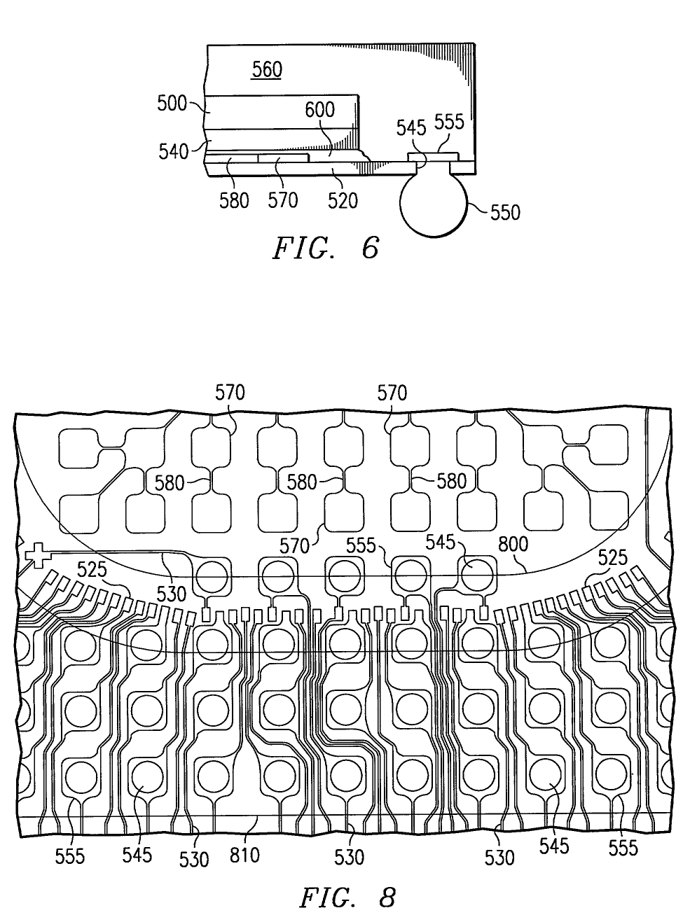

Referring to FIG. 5, a cutaway view of the embodiment package is shown. Substrate 520 is the foundation of the package. The substrate may be a flexible tape comprising a material such as polyimide, for example, a relatively rigid laminate of polymer resins such as bismaleimide triazine (BT), or a ceramic. In this embodiment, the substrate is 75 μm thick polyimide tape. Holes approximately 280 μm in diameter are punched, etched, laser- or mechanically-drilled through the substrate to form vias 545. Via cap metal 555 over vias 545 provides a base to which solder balls 550 can be attached with solder paste, for example. Via cap metal 555 overlaps the edge of the via by approximately 30 μm. In this embodiment, the solder balls are 300 μm in diameter and made of tin/lead whereas the solder paste is tin/silver. Additional via cap patterns 570 are formed on the substrate 520 in the region beneath the chip 500. Via cap patterns 570 are connected by cross-links 580. In this embodiment, cross-links 580 are formed of the same via cap metal as via cap patterns 570. The via cap metal in this embodiment is an approximately 25 μm-thick layer of copper. It should be appreciated that other thicknesses and metallization schemes could also be employed to similar advantage. The entire layer of via cap metal can be plated with 0.5 μm of nickel and 0.5 μm of gold, for example, to prevent oxidation of the copper which can lead to delamination of package components. In this embodiment, however, it is preferable to save the cost of plating the via cap patterns 570 and the cross-links 580 that are beneath the chip 500. It is possible to eliminate the plating of that portion of the via cap metal layer in this embodiment because it is covered with a solder mask layer (shown in FIG. 6, but not shown in FIG. 5). The solder mask protects the copper from oxidation, enhances adhesion of the chip and other package components to the substrate 520, and reduces the moisture sensitivity of the package. The solder mask is applied to the substrate prior to the plating steps and thus acts as a mask to prevent the plating of the grid.

FIG. 6 is a cross-sectional view of the package of FIG. 5 showing the relation of via cap pattern 570 and cross-link 580 to other key components of the package. Via cap metal 555 covers via 545 in substrate 520. Solder ball 550 is attached to via cap metal 555 from the second surface of substrate 520, i.e. the surface opposing the surface upon which chip 500 is mounted using die attach 540. Solder mask 600 covers via cap pattern 570 and cross-links 580. Solder mask 600 is optional, but is known by the inventors to provide enhanced adhesion of chip 500 to substrate 520. Encapsulant 560 covers the entire structure. In this embodiment, the die attach 540 is epoxy and is approximately 100 μm thick. Solder mask 600 is also epoxy and is approximately 10 μm thick. Encapsulant 560 is epoxy as well, and is approximately 800 μm thick.

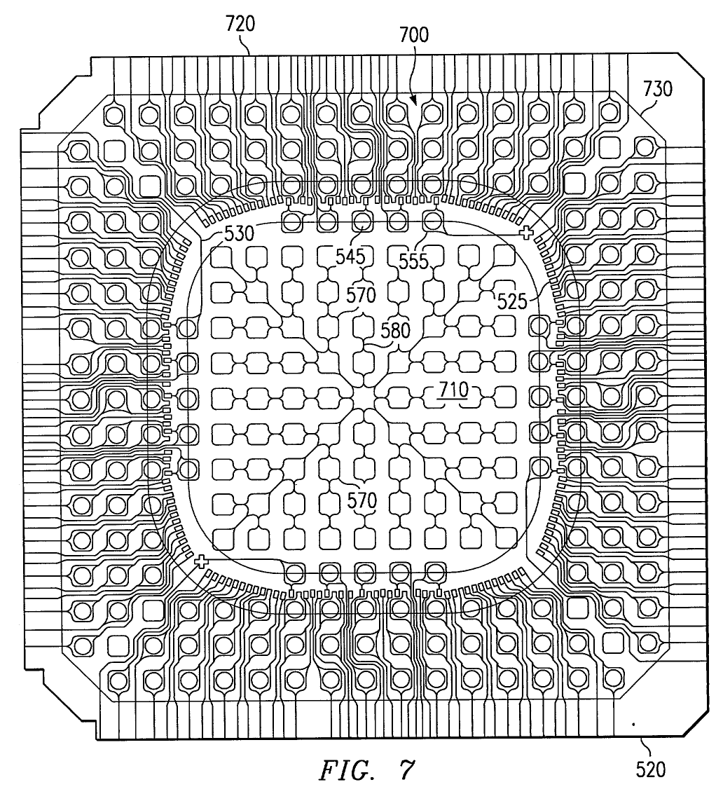

FIG. 7 is a plan view of a substrate according to the embodiment of the invention shown in FIG. 5. Substrate 520 includes a peripheral portion 700 and a central portion 710. The chip (not shown) is mounted over the central portion 710. Wires (not shown) are bonded to pads on the chip and to lands 525. Lands 525 are connected by conductive traces 530 to via caps 555 which cover vias 545. One skilled in the art will appreciate that via caps cover the vias, and that the vias would therefore not normally be visible in a plan view of the top or first surface of the substrate. The via locations are shown in this view to clarify their relationship to the other package components. Conductive traces extend to the edge 720 of substrate 520 to provide a conductive path to all parts of the metal layer that are to be electroplated. The traces beyond the boundary 730 will be removed upon singulation of the package.

Via cap patterns 570 and cross-links 580 are shown in FIG. 7 in a configuration that creates a grid in the central portion 710 of the substrate. The superior thermal conductance of the metal grid (as compared to the substrate) results in increased dissipation of heat from the chip. The grid acts as a heat spreader and increases copper content of the package. The implementation of this grid is relatively straightforward in that a simple change to the masks used in forming the via cap metal pattern is all that is required. This allows for a relatively inexpensive way to retrofit existing substrate designs with improved thermal performance. For new designs, this approach incurs no additional cost to obtain enhanced thermal performance. As mentioned above, this simple technique results in a 5% to 10% improvement in thermal dissipation over a substrate design that is devoid of metallization in its central portion 710 (such as is shown in prior art FIG. 3). Although the grid is shown as being formed of via cap patterns 570 interconnected by cross-links 580, one skilled in the art will appreciate that other grid patterns or even a solid sheet of metal could be used in the alternative. However, the via cap pattern shown here offers the advantage of conforming to existing substrate design rules. The cross-links also conform with the design rules for conductive metal traces 530. The preferred embodiment therefore requires no additional testing to ensure that it conforms to existing reliability standards. By forming the grid from patterns and lines used elsewhere on the substrate, the design is unlikely to introduce yield or reliability risk into an existing substrate design.

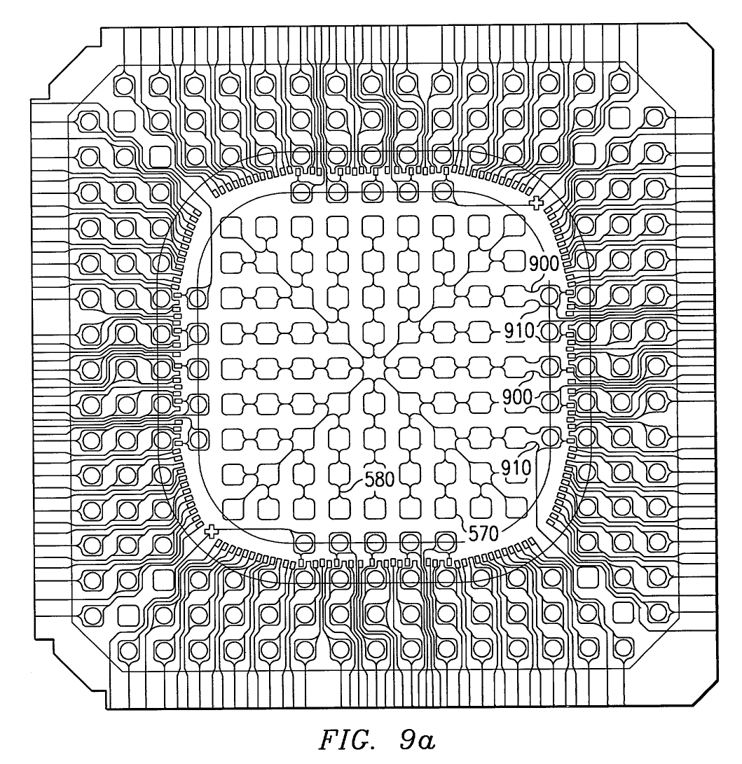

FIG. 8 shows a portion of the substrate layout of FIG. 7 in greater detail. The edge of the chip (not shown) will be at the approximate location shown by line 800. The chip covers the grid of via cap patterns 570 and cross-links 580. Lands 525 are placed near the chip edge 800 and will be connected to bond pads on the chip by bond wires (not shown). Lands 525 are connected to via caps 555 by conductive traces 530. Again, vias 545 are shown in this view for clarity. The conductive traces 530 extending beyond line 810 will be removed when the package is singulated following encapsulation.

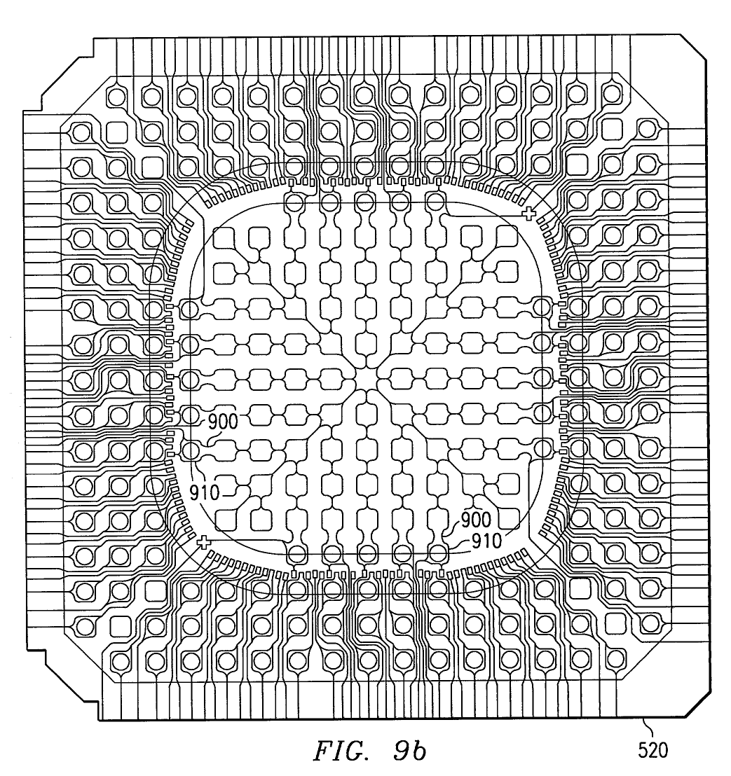

In another embodiment of the invention, illustrated in FIGS. 9a and 9b, the grid is modified by connecting it to electrically-connected via caps that are in turn connected to solder balls attached to a higher level of interconnection such as a printed circuit board. The preferred connection is to solder balls connected to electrical ground since a typical ground circuit is suitable for dissipating thermal energy in the printed circuit board. In the alternative, the connection could be made to a ball connected to a power supply, or even to an appropriate signal line, if it is suitably arranged to dissipate thermal energy produced by the chip. The grid functions as in the embodiment described above, but this embodiment offers the additional benefit of providing a thermal path out of the package through attached solder balls. In FIG. 9a, the grid of via cap patterns 570 and cross-links 580 appear the same as shown in FIG. 7. However, the grid is connected by traces 900 to via caps 910 that are connected to balls that are in turn connected to ground. The grid is shown in FIG. 9a to be connected to five different via caps, but fewer or more ground connections could be used depending upon the thermal dissipation requirements of a particular IC. For example, in FIG. 9b, the grid is shown to have twenty connections of traces 900 to via caps 910. Note that the ground via caps and their associated solder balls serve the electrical role of providing electrical ground connections to the chip. They are therefore not thermal solder balls (i.e. via caps/solder balls which are electrically unconnected) as used in the prior art approach. By using existing, electrically-connected via caps/balls, this approach avoids the costs and risk involved with using dedicated thermal balls as in the prior art, while still providing enhanced thermal performance. Indeed, research conducted by the inventors shows that this approach can result in as much as 25% to 30% improved heat dissipation when compared to the prior art substrate design shown in FIG. 3.

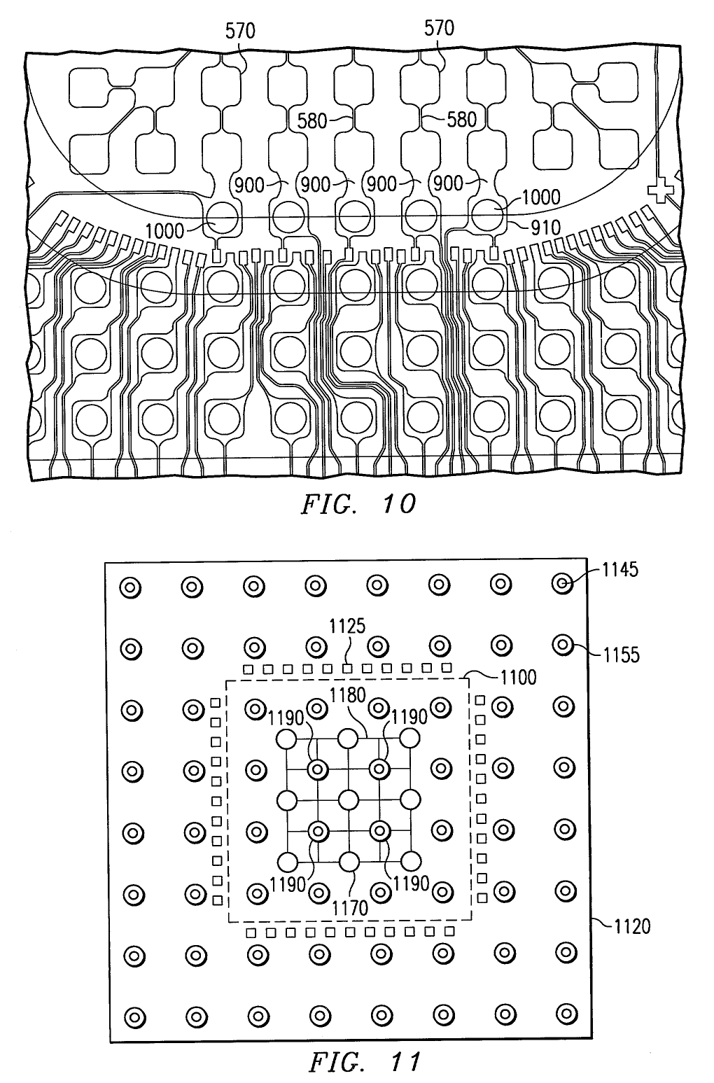

FIG. 10 shows a portion of the layout of FIG. 9a in more detail. Five connections 900 are shown between the grid made up of via cap patterns 570 and cross-links 580 and via caps 910 coupled through vias 1000 to solder balls that provide a thermal path out of the package onto the printed circuit board, for example, to which the package is ultimately attached.

FIG. 11 shows a plan view of a substrate in another embodiment of the invention. Substrate 1120 is shown with solder caps 1155 covering vias 1145. In this embodiment, the vias (and hence the solder balls that are ultimately attached to the bottom surface of the substrate) are arranged uniformly across the substrate in a so-called “area array”. The chip will eventually be placed in the center of the substrate, and therefore the chip boundary, shown as dashed line 1100, covers some of the vias 1145. Bonding lands 1125 are arranged around the perimeter of the chip boundary and are connected by conductive traces to the solder cap metal 1155 that covers the vias. These traces are not shown in FIG. 11 to preserve clarity. This area array substrate layout can make use of the inventive concepts disclosed herein as shown in the central portion of FIG. 11. Solder cap patterns 1170 and cross-links 1180 are interleaved with the array of vias to form the heat dissipating grid discussed hereinabove. In this case, the four inner vias 1190 are shown integrated into the grid. In this embodiment these vias are connected to solder balls connected electrical ground. They therefore serve as the connection of the heat dissipating grid to the external environment (through the electrical ground path out of the package) as described above in the embodiment shown in FIG. 9.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. For example, the preferred embodiments described herein have been face-up, wire-bonded ball grid array packages. One skilled in the art will appreciate that the inventive concepts could be applied to other forms of packaging such as land grid arrays and flip chip packages as well. It is contemplated that such modifications and alternatives are within the scope of this invention as claimed hereinbelow.

We claim:

1. A packaged integrated circuit, comprising:
a substrate including a metal grid over a top surface of said substrate; and
an integrated circuit chip mounted on said substrate over said grid.

2. The packaged integrated circuit of claim 1, wherein said metal grid is electrically isolated from said integrated circuit.

3. The packaged integrated circuit of claim 1, wherein said metal grid is electrically connected to said integrated circuit.

4. The packaged integrated circuit of claim 3, wherein said connection is through electrical ground.

5. The packaged integrated circuit of claim 1, wherein said integrated circuit chip comprises an active top surface upon which circuits are formed and a bottom surface, and further wherein said bottom surface of said chip is attached to said substrate over said grid.

6. The packaged integrated circuit of claim 1, wherein said substrate further comprises vias coupling a metal layer on said top surface of said substrate to solder balls on a bottom surface of said substrate, and further wherein said grid is formed in said metal layer.

7. A packaged integrated circuit, comprising:
a substrate having a central portion and a peripheral portion, said substrate including vias in said peripheral portion and no vias in said central portion, said vias in said peripheral portion covered on one side of said substrate with metal caps, said metal caps formed in a single layer of metal,
said substrate further including a metal grid in said central portion of said substrate wherein said metal grid is formed in said single layer of metal, and further wherein said metal grid comprises interconnected via cap patterns; and
an integrated circuit chip mounted on said substrate over said grid.

8. The packaged integrated circuit of claim 7, wherein said metal grid is electrically isolated from said integrated circuit.

9. The packaged integrated circuit of claim 7, wherein said metal grid is electrically connected to said integrated circuit.

10. The packaged integrated circuit of claim 9, wherein said connection is through electrical ground.

11. The packaged integrated circuit of claim 7, wherein said integrated circuit chip comprises an active top surface upon which circuits are formed and a bottom surface, and further wherein said bottom surface of said chip is mounted on said substrate over said grid.

12. The packaged integrated circuit of claim 7, wherein said chip and said substrate are covered by an encapsulant.

13. A method for fabricating a packaged integrated circuit, comprising the steps of:
providing a substrate;
forming a metal grid on a central portion of said substrate; and
mounting an integrated circuit chip over said metal grid.

14. The method of claim 13, further comprising the step of electrically isolating said metal grid from said integrated circuit.

15. The method of claim 13, further comprising the step of electrically connecting said metal grid to said integrated circuit.

16. The method of claim 15, wherein said step of electrically connecting said metal grid comprises connecting said grid to electrical ground.

17. The method of claim 13, wherein said step of mounting said integrated circuit chip comprises attaching a bottom surface of said chip to said substrate over said metal grid.

18. The method of claim 13, wherein said step of providing a substrate further comprises the step of providing vias in said substrate coupling a metal layer on said top surface of said substrate to solder balls on a bottom surface of said substrate, and further wherein said step of forming said grid comprises forming said grid in said metal layer.
